(19) United States
(12) Patent Application Publication
(10) Pub. No.: US 2006/0097403 A1
(43) Pub. Date: May 11, 2006

(54) No-flow underfill materials for flip chips

(76) Inventors: Vassoudevane LeBonheur, Tempe, AZ (US); Terrence C. Caskey, Phoenix, AZ (US)

Correspondence Address: INTEL/BLAKELY, 12400 WILSHIRE BOULEVARD, SEVENTH FLOOR, LOS ANGELES, CA, 90025-1030, US

(21) Appl. No.: 10/985,428

(22) Filed: Nov. 10, 2004

(51) Int. Cl. H01L 21/48; H01L 23/48; H01L 21/50; H01L 23/52; H01L 21/44; H01L 29/40

(52) U.S. Cl. 257/778; 438/108

(57) ABSTRACT

Systems and methods are described which include packaging semiconductor dies and next level packages using low viscosity no-flow underfills having fine fillers treated with surface treatment agents.

### BACKGROUND INFORMATION

Modern semiconductor designs have achieved a high level of sophistication, incorporating a wide variety of materials into small, high performance devices. Some of the materials employed may have disparate properties, however, which may lead to manufacturing difficulties and reliability failures.

An approach to ameliorating residual stresses in flip chip or controlled collapse chip connection (C4) devices involves forming an underfill between the semiconductor die and the substrate. Traditionally, this underfill is formed by flowing an underfill mixture between the semiconductor die and the substrate after the die has been bonded to the substrate. In this approach, the underfill mixture is drawn between the die and the substrate by capillary action. However, as device sizes have decreased and the number of input/output and other connections to the semiconductor die has increased, it has become more difficult to utilize this capillary underfill approach.

The difficulties in utilizing capillary underfills have led to efforts to develop so called “no-flow” underfills. Unlike capillary underfills, no-flow underfills are put in place before the die is bonded to the substrate. For example, the no-flow underfill may be formed on the substrate before the die is bonded to the substrate, though the underfill may be formed on the die, or on both the die and the substrate. After the underfill is formed on the substrate, the die may be placed in contact with the substrate and the resulting assembly heated to form electrical connections between the die and the substrate, a process known as reflowing. This heating may also cause the no-flow underfill to harden or cure.

As used herein, no-flow underfill refers to an underfill which is put in place before a die-next level package assembly is reflowed to form electrical or other connections between the die and the next level package. Also known as NUF or predispensed underfill, no-flow underfill is to be distinguished from a traditional capillary underfill, which is put in place through capillary action after a die-next level package assembly has been reflowed.

No-flow underfill materials according to some embodiments of the present invention are novel approaches to problems which have impeded the implementation of no-flow underfills. The implementation of no-flow underfills in flip chips presents difficulties arising from the fact that these underfills are put in place before interconnects are formed between the semiconductor die and the next level package. It may be desirable to match the coefficient of thermal expansion of the no-flow underfill to that of the interconnects, but attempts to reduce the coefficient of thermal expansion of no-flow underfills through the addition of fillers to the underfill can result in underfill material becoming entrapped in interconnect solder joints. Filler entrapment can lead to reduced current carrying capabilities and electrical opens, causing yield problems and reliability issues. This pushes semiconductor designers to choose no-flow underfills without fillers that exhibit high coefficients of thermal expansion.

### BRIEF DESCRIPTION OF THE DRAWINGS

Some embodiments of the present invention are illustrated, by way of example and not limitation, in the accompanying figures, in which like references indicate similar elements and in which:

FIGS. 1-5 illustrate an electronic component with a no-flow underfill according to some embodiments of the present invention.

FIG. 6 is a flow chart illustrating a method for making an electronic component according to some embodiments of the present invention.

FIG. 7 is a flow chart illustrating a method for making a no-flow underfill according to some embodiments of the present invention.

FIG. 8 is a block diagram representing a simplified view of an electronic system including one or more electronic components according to some embodiments of the present invention.

### DETAILED DESCRIPTION

In the following description numerous specific details are set forth. However, it is understood that some embodiments may be practiced without these specific details. It is also understood that the description of particular embodiments is not to be construed as limiting the disclosure to those embodiments. Well-known circuits, structures and techniques have not been shown in detail in order not to obscure the understanding of this description.

As used herein, next level package refers to any type of packaging bonded to the semiconductor die. A next level package may be a substrate, a flexible substrate, an interposer, a printed wiring board, and/or any other suitable component.

As used herein, binder, or binder system, refers to any type of material that is capable of adhering to the semiconductor die and the next level package. A binder may include, for example, a thermoset epoxy resin, though embodiments of the present invention are not limited thereto.

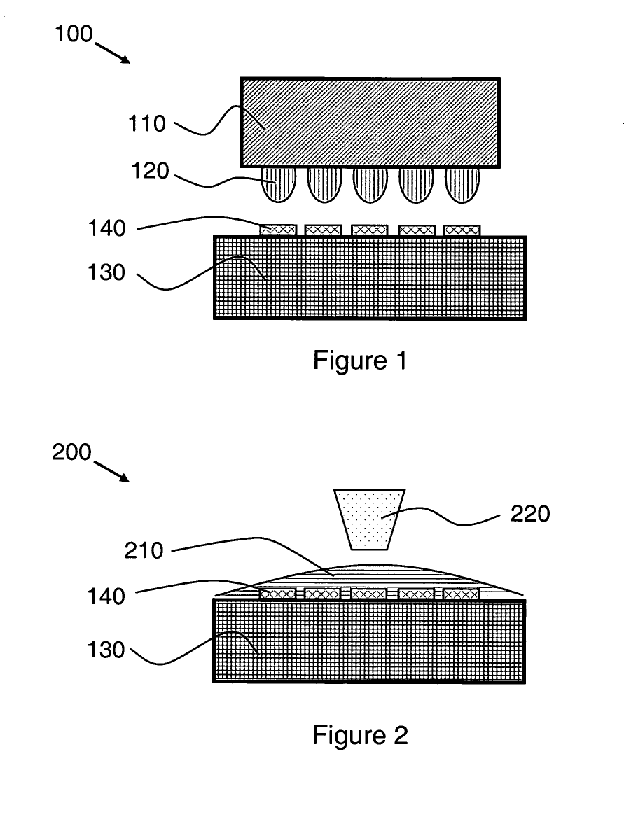

FIGS. 1-5 illustrate semiconductor components with a no-flow underfill according to some embodiments of the present invention. FIG. 1 illustrates a semiconductor die 110 and a next level package 130 before they are joined. Die 110 and next level package 130 may be joined as shown in FIGS. 2-5.

In FIG. 1, semiconductor die 110 has an array of interconnect features 120 on a first surface. Semiconductor die 110 may include, for example, active devices, low-k dielectric layers and/or copper traces. Interconnect features 120 may include, for example, copper bumps and silver-tin solder. Also shown in FIG. 1 is next level package 130 with an array of pads 140. Next level package 130 may include, for example, a substrate, a flexible substrate, an interposer, a printed wiring board and/or any other suitable component.

In FIG. 2, no-flow underfill 210 is shown dispensed, in an uncured state, onto next level package 130 via dispenser 220. In some embodiments, dispenser 220 may dispense no-flow underfill 210 onto semiconductor die 110, or onto both next level package 130 and semiconductor die 110. Dispenser 220 may dispense no-flow underfill 210 as a single point, a series or array of points, a line, an “L” shape, or any other suitable application geometry.

In some embodiments, no-flow underfill 210 may include fillers, surface treatment agents, binders, fluxing agents, wettability agents, hardeners, catalysts, and/or inhibitors. The filler may include fine particles which have been modified with a surface treatment agent. In some implementations the filler includes fine silica particles having an average size of less than about 1 μm (micrometer; micron). The use of fine filler particles may enable improved mobility of the filler in uncured no-flow underfill 210. No-flow underfill 210 may include from about 1% to about 70% by weight of filler. In some embodiments, no-flow underfill preferably includes from about 40% to about 60% by weight of filler.

Surface treatment agents may be chosen, at least in part, based on the binder system, such that surface treatment molecules include moieties which are compatible with, and conform to, the binder environment. In some implementations the surface treatment agent may be a trialkoxy silane. Surface treatment agents may conform so as to improve dispersion of surface treated filler particles in the uncured binder. Improving dispersion may reduce the settling or clumping of filler particles and help reduce the chances of localized, high concentrations of filler particles which, if entrapped in an interconnect solder joint, may reduce reliability and increase electrical failures.

In some implementations, wettability agents may include moieties that reduce the viscosity and improve wettability of the uncured no-flow underfill system. This may promote the flow of material from the interconnect solder joint 120 to pad 140 contact area during reflow to reduce entrapment of material in the joint. It may also improve the wetting properties of the system toward, for example, a substrate solder mask. Wettability, also referred to as the wetting angle or contact angle, may improve flow across, and bonding to, semiconductor die 110 and next level package 130 surfaces, and may reduce voids and improve bonding strength.

In some implementations, filler surface treatment agents may include functionality capable of coupling with the binder system. Surface treatment agents that couple with the binder system may promote high adhesion strength between the filler and the binder system and may improve reliability and performance over extended use. For example, surface treatment agents may include hydroxyl or phenolic functionality capable of reacting with an epoxy resin in an epoxy binder system. Similarly, surface treatment agents may include epoxide functionality capable of reacting with a hardener in an epoxy binder system. These moieties may remain reactive towards the binder system after the surface treatment agent has been applied to the filler; they may react with the binder system during reflow of the interconnect elements 120 and curing of the no-flow underfill 210 to cross link the filler and surface treatment agent to the binder system.

The binder system may exhibit low viscosity at reflow temperature. For example, where epoxy resins are implemented, they may include low molecular weight epoxide monomers. Viscosity at reflow temperature may also be adjusted, for example, by controlling filler loading, the surface treatments applied to filler particles, and, as discussed below, by controlling cure kinetics. The viscosity of uncured no-flow underfill 210 may be less than or equal to about 1 Pa-sec (Pascal-second) at interconnect solder joint 120 reflow temperature.

In some implementations, the binder components may include a thermoset epoxy, though other binder components having suitable characteristics may also be employed. Where the binder includes a thermoset epoxy, it may include an epoxy resin having functionality greater than two, such as a low molecular weight bisphenol A type resin, to promote cross linking and enhance thermal and mechanical stability. For example, no-flow underfill 210 may include from about 50% to about 90% by weight of an epoxy resin.

The filler and binder components may be combined with a fluxing agent and/or a wettability agent. Fluxing agents may be any materials compatible with other components of the no-flow underfill 210 and suitable for removing metal oxides from the joints which form the interconnects between the semiconductor die 110 and the next level package 130. Wettability agents such as surfactants may be employed to improve the wetting properties of the underfill toward, for example, a substrate solder mask.

Fluxing agents may be provided in relatively high concentrations and/or with high levels of activity to promote solder wetting which may displace underfill material from the interconnect solder joint 120 to pad 140 interface during reflow. Strong fluxing capability may promote removal of oxide from the solder bumps and promote the thermodynamic driving force for molten solder to wet pads 140, which may enable molten solder to expel no-flow underfill material 210 from the interconnect solder joint 120 to pad 140 contact area. Fluxing agents may possess low volatility to help maintain their effectiveness during the reflow process. For example, suitable fluxing agents may include organic acids, acid precursors such as esters or anhydrides, or n-octanoic acid. Wettability agents may include, for example, functionalized silanes, fluorinated methacrylates, or sulfates of fatty alcohols. No-flow underfill 210 may include from about 0% to about 5% by weight of a fluxing agent and/or up to about 2% of a wettability agent.

No-flow underfill 210 may optionally include a hardener, a catalyst, and/or an inhibitor. If the binder employed in no-flow underfill 210 includes an epoxy resin, then the hardener may be a nucleophilic material capable of reacting with the epoxy resin. Such a hardener may have a reactive functionality of greater than two. Hardeners may have, for example, phenolic, anhydride, or amine functionality.

Catalysts, if employed, may be any material suitable for accelerating or otherwise controlling the cure kinetics of the binder system. Where the binder is a thermoset epoxy, catalysts may include imidazole, triphenyl phosphine, and/or polymer-encapsulated catalysts. Cure kinetics of the binder system may be controlled so that the no-flow underfill gel point occurs after interconnect solder joint 120 reflow. Since the viscosity of the binder system increases significantly at the gel point, controlling cure kinetics in this manner may maintain desirable viscosity characteristics prior to bump melting and interconnect joint formation. Reduced viscosity may allow underfill material to escape or be displaced from interconnect solder joints to reduce material entrapment during the relatively fast reflow process.

Controlling the cure kinetics may be achieved through the use of slow and/or latent catalysts, low catalyst concentrations, and/or inhibitors. Inhibitors, if employed, may be any material suitable for slowing or otherwise controlling the cure kinetics of the binder system. Those skilled in the art will appreciate that controlling reaction kinetics so that the gel point occurs after solder joint reflow may involve a detailed understanding of process factors such as reflow heating ramp rates and reflow temperatures, since the reaction kinetics of the binder system may also depend on these factors. No-flow underfill 210 may include up to about 1% by weight of catalysts and/or inhibitors.

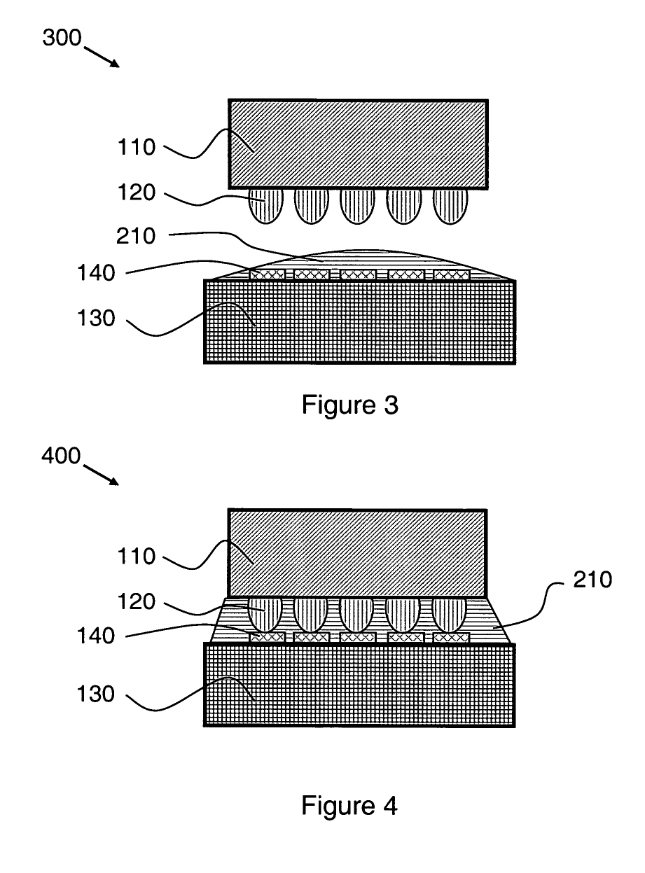

In FIG. 3, semiconductor die 110 is brought into alignment with next level package 130. For example, where semiconductor die 110 is a flip chip, it may be aligned with next level package 130 such that interconnect features 120 are aligned with pads 140. Semiconductor die 110 and next level package 130 are arranged with uncured no-flow underfill 210 disposed between them.

In FIG. 4, the die-package assembly 400 is shown ready for reflow. Semiconductor die 110 is brought into contact with next level package 130 such that uncured no-flow underfill 210 is disposed between them and interconnect features 120 are aligned and in contact with corresponding pads 140 on next level package 130.

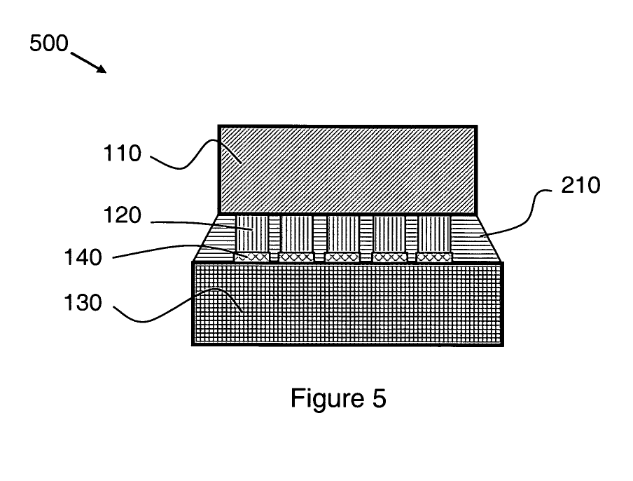

In FIG. 5, the die-package assembly 500 is shown after reflow and cooling. The reflow process heats interconnect features 120 and no-flow underfill 210, causing interconnect features 120 to bond to pads 140 on next level package 130 and causing no-flow underfill 210 to cure.

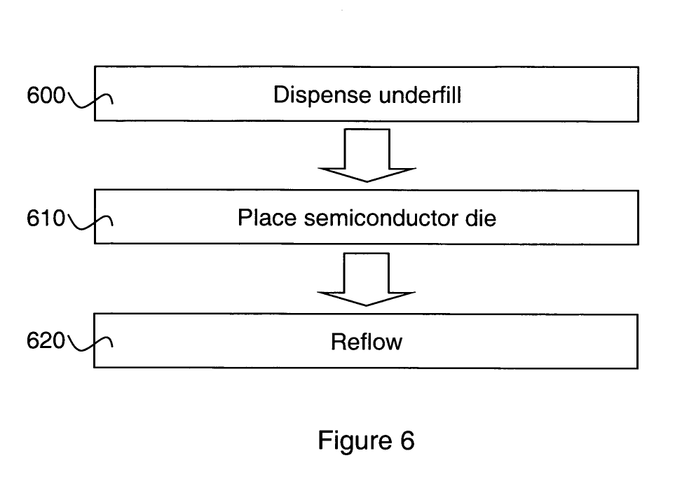

FIG. 6 is a flow chart illustrating a method for making an electronic component including a no-flow underfill according to some embodiments of the present invention. In Block 600, uncured no-flow underfill 210 is dispensed on a next level package 130. In Block 610, an assembly 400 is formed by bringing a semiconductor die 110, having an array of interconnect elements 120, into contact with next level package 130 such that uncured no-flow underfill 210 is disposed between them and such that interconnect elements 120 are aligned with corresponding pads 140 on next level package 130.

In Block 620, assembly 400 formed in Block 610 is heated to reflow temperature and subsequently cooled. The viscosity of uncured no-flow underfill 210 may be less than or equal to about 1 Pa-sec (Pascal-second) at the interconnect reflow temperature. Reflowing causes interconnect elements 120 to bond semiconductor die 110 to next level package 130 and causes no-flow underfill 120 to cure.

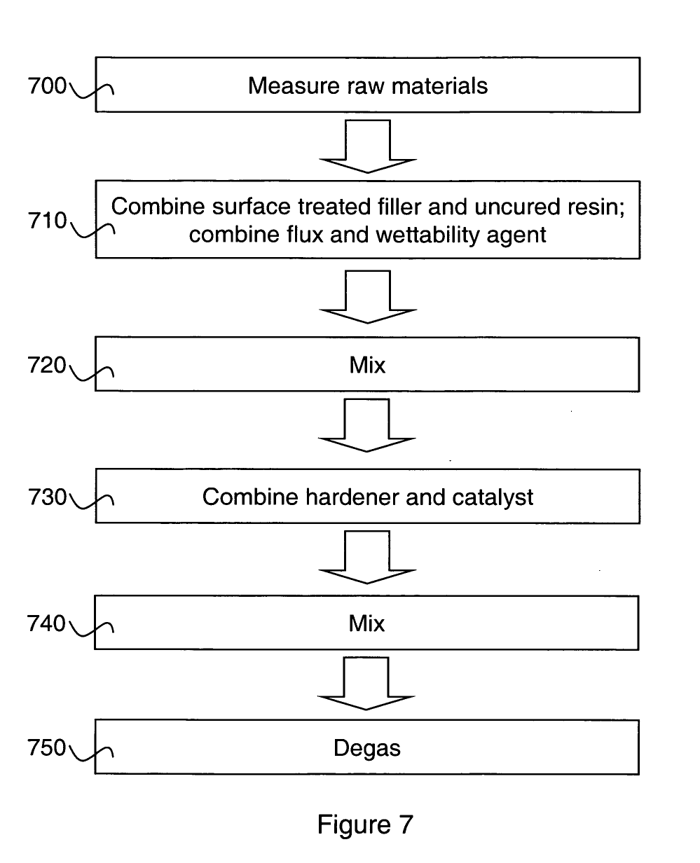

FIG. 7 is a flow chart illustrating a method for making a no-flow underfill according to some embodiments of the present invention. In Block 700, raw materials, including binder components and fillers, are measured out. Other preliminary operations may also included, such as adjusting moisture levels in the raw materials.

In Block 710, filler and one or more binder components are combined. The filler may include fine particles which have been modified with a surface treatment agent. In some implementations the filler includes fine silica particles having an average size of less than about 1 μm.

Surface treatment agents may be chosen, at least in part, based on the binder system, such that surface treatment molecules include moieties which are compatible with, and conform to, the binder environment. In some implementations the surface treatment agent may be a trialkoxy silane. In some implementations, surface treatment agents may include moieties that reduce the viscosity and improve wettability of the uncured no-flow underfill system. In some implementations, surface treatment agents may include functionality capable of coupling with the binder system.

In some implementations, the binder components may include a thermoset epoxy, though other binder components having suitable characteristics may also be employed. Where the binder includes a thermoset epoxy, it may include an epoxy resin having functionality greater than two, such as a low molecular weight bisphenol A type resin, to promote cross linking and enhance thermal and mechanical stability. The viscosity of no-flow underfill 210 before curing may be less than or equal to about 1 Pa-sec at reflow temperature.

Also in Block 710, the filler and binder components may be combined with a fluxing agent and/or a wettability agent. Fluxing agents may be any materials compatible with other components of the no-flow underfill 210 and suitable for removing metal oxides from the joints which form the interconnects between the semiconductor die 110 and the next level package 130. Fluxing agents may be provided in relatively high concentrations and/or with high levels of activity to promote solder wetting which can displace underfill material from the interconnect solder joint 120 to pad 140 interface during reflow. Suitable fluxing agents may include organic acids, acid precursors such as esters or anhydrides, or n-octanoic acid. Wettability agents such as surfactants may be employed to improve the wetting properties of the underfill toward the substrate solder mask. Wettability agents may include, for example, functionalized silanes, fluorinated methacrylates, or sulfates of fatty alcohols.

In Block 720, the components from Block 710 are optionally mixed, for example by using a three-roll kneader. Filler particle dispersion in the uncured no-flow underfill may be improved thereby.

In Block 730, the components from Block 710 are optionally combined with a hardener, a catalyst, and/or an inhibitor. If the binder employed in Block 710 includes an epoxy resin, then the hardener may be a nucleophilic material capable of reacting with the epoxy resin. Such a hardener may have a reactive functionality of greater than two. Hardeners may have, for example, phenolic, anhydride, or amine functionality. Catalysts, if employed, may be any material suitable for accelerating or otherwise controlling the cure kinetics of the binder system. Where the binder is a thermoset epoxy, catalysts may include imidazole, triphenyl phosphine, and/or polymer-encapsulated catalysts. Inhibitors, if employed, may be any material suitable for slowing or otherwise controlling the cure kinetics of the binder system.

In Block 740, the components from Block 730 are optionally mixed, for example by using a three-roll kneader. In Block 750, the components are optionally degassed, for example by applying a vacuum.

In some embodiments, the resulting combination of materials includes the following:

| Material | Weight % |
|---|---|
| Silica filler particles having an average size of less | about 1-70%; |
| than about 1 um, treated with a silane surface | preferably |
| treatment having functionality capable of reacting | 40-60% |
| with one or more components of an epoxy resin | |
| Epoxy resin, having functionality of greater than two | about 50-90% |
| Fluxing agent | about 1-5% |
| Wettability agent | about <2% |
| Hardener, having functionality of greater than two | about 2-50% |
| Catalyst | about <1% |

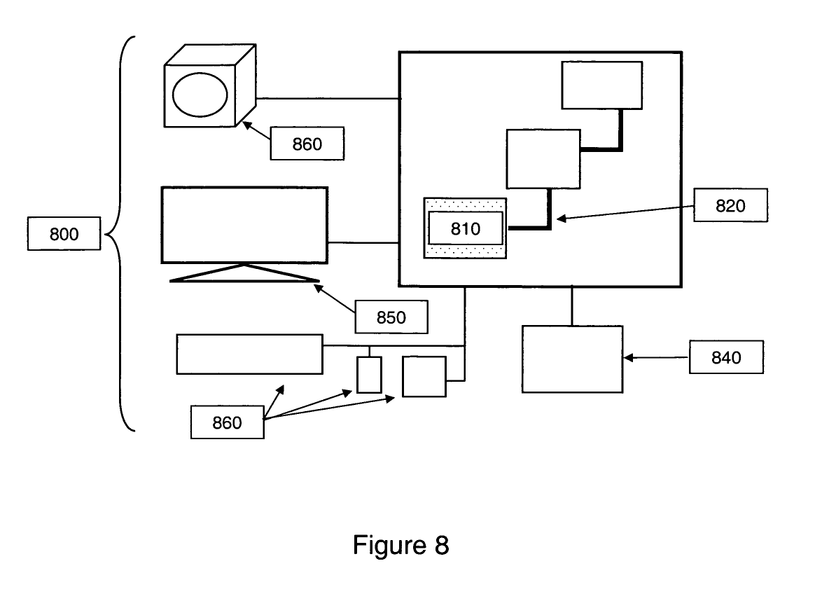

FIG. 8 is a block diagram representing a simplified view of an electronic system including one or more electronic devices according to some embodiments of the present invention. Electronic system 800 includes an electronic component 810 which is electrically coupled to various components in electronic system 800 via system bus 820 and/or other cabling. Some interconnections between the various components are not shown in the interest of clarity. Electronic component 810 is made according to some embodiments of the present invention, such as is shown in FIGS. 1-5. Electronic component 810 may optionally include a microprocessor, microcontroller, chip set, graphics processor or digital signal processor, and/or a custom circuit or an application-specific integrated circuit, such as a communications circuit. System bus 820 may be a single bus or any combination of busses.

Electronic system 800 may also include an external memory 840 that in turn includes one or more memory elements suitable to the particular application, such as a main memory in the form of random access memory, one or more hard disc drives, and/or one or more drives that handle removable media such as floppy diskettes, compact discs or digital video discs.

Electronic system 800 may also include a display component 850, an audio component 860, and one or more controllers 860, such as a keyboard, mouse, joystick, scanner, or any other component that inputs information into the electronic system 800.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

What is claimed is:

1. A packaging system comprising:
a die and a next level package;
a plurality of interconnects disposed between a surface of the die and a surface of the next level package, the interconnects coupling the die and the next level package when heated to a reflow temperature; and
a curable underfill mixture disposed between the surface of the die and the surface of the next level package before the interconnects are heated to the reflow temperature, the underfill having a viscosity of about 1 Pascal-second or less at the reflow temperature and before curing.

2. The packaging system of claim 1, wherein the curable underfill mixture includes a filler, the filler having an average particle size of about 1 μm or less and treated with a surface treatment agent.

3. The packaging system of claim 2, wherein the filler includes silica and the surface treatment agent includes a silane.

4. The packaging system of claim 3, wherein the curable underfill mixture includes an epoxy and the surface treatment agent includes a reactive hydroxyl group, a reactive phenolic group, or a reactive epoxide group.

5. The packaging system of claim 4, further comprising a wettability agent.

6. A die package comprising:
a die including an active surface;
a substrate including a first surface that faces the active surface;
electrical coupling between the active surface and first surface; and
a no-flow underfill between the active surface and the first surface, wherein the no-flow underfill includes a binder and a filler having an average size of about 1 μm or less and treated with a surface treatment agent, the surface treatment agent including at least one moiety capable of reacting with the binder.

7. The die package of claim 6, wherein the filler includes silica and the surface treatment agent includes a silane.

8. The die package of claim 6, wherein the binder includes a thermoset epoxy.

9. The die package of claim 8, wherein the binder includes an epoxy resin having a functionality of greater than two.

10. The die package of claim 9, wherein the at least one moiety includes a hydroxyl group, a phenolic group, or an epoxide group.

11. The die package of claim 6, wherein the no-flow underfill is cured by application of heat, and wherein the no-flow underfill has a viscosity of about 1 Pascal-second or less before curing.

12. The die package of claim 11, further including a fluxing agent.

13. A process comprising:
providing a curable underfill having a viscosity of about 1 Pascal-second or less at a reflow temperature and before curing;
forming an arrangement including a die, a plurality of interconnects, a next level package and the curable underfill such that the interconnects and the curable underfill are disposed between the die and the next level package; and
subsequently causing the interconnects to couple the die with the next level package.

14. The process of claim 13, wherein the curable underfill includes a filler having an average size of less than about 1 μm, the filler treated with a surface treatment agent.

15. The process of claim 14, further including at least partially curing the curable underfill while heating the arrangement to the reflow temperature and causing the curable underfill to reach a gel point after the arrangement reaches the reflow temperature.

16. A process comprising:
providing a no-flow underfill that includes a binder and a filler, the filler having an average size of less than about 1 um and treated with a surface treatment agent, the surface treatment agent including at least one reactive moiety to react with the binder;
forming an arrangement including a next level package, a die, the no-flow underfill, and a plurality of interconnects, the interconnects having a reflow temperature, wherein the interconnects and the no-flow underfill are disposed between the die and the next level package; and
causing the interconnects to couple the next level package with the die.

17. The process of claim 16, wherein the no-flow underfill includes an epoxide-containing resin and the reactive moiety includes a nucleophilic group.

18. The process of claim 16, wherein the no-flow underfill includes a hardener having at least one nucleophilic group and the reactive moiety includes an epoxide group.

19. A no-flow underfill comprising:
a binder; and
a filler having an average particle size of about 1 μm or less and treated with a surface treatment agent;
wherein the underfill exhibits a viscosity before curing of about 1 Pascal-second or less when heated to between about 150 degrees centigrade and about 250 degrees centigrade.

20. The no-flow underfill of claim 19, wherein the binder comprises a thermoset epoxy.

21. The no-flow underfill of claim 19, wherein the binder comprises an epoxy resin and a hardener, the epoxy resin and the hardener each having a functionality greater than two.

22. The no-flow underfill of claim 21, wherein the surface treatment agent has functionality capable of coupling with the epoxy resin or the hardener or both.

23. The no-flow underfill of claim 19, comprising from between about 1% to about 70% of filler by weight.

24. The no-flow underfill of claim 21, comprising from between about 50% to about 90% of epoxy resin by weight.

25. The no-flow underfill of claim 24, comprising from between about 2% to about 50% of hardener by weight.

26. The no-flow underfill of claim 25, further comprising a fluxing agent.

27. An electronic system, comprising:
a chip package within a housing, the chip package including a die and a next level package with a no-flow underfill disposed between a surface of the die and a surface of the next level package;
an input device interfaced with the chip package; and
a display device interfaced with the chip package,
wherein the no-flow underfill includes a binder and a filler having an average particle size of about 1 μm or less and treated with a surface treatment agent, the surface treatment agent including at least one moiety capable of reacting with the binder.

28. The system of claim 27, wherein the binder includes a thermoset epoxy and the no-flow underfill has a viscosity of about 1 Pascal-second or less when heated to a reflow temperature and before curing.

29. The system of claim 28, wherein the no-flow underfill includes an epoxy resin with a functionality of two or more.
